(19) United States
(12) Patent Application Publication
(10) Pub. No.: US 2025/0251469 A1
(43) Pub. Date: Aug. 7, 2025

(54) SYSTEMS AND METHODS FOR DETECTING AND MITIGATING INTERMITTENT CONNECTIONS IN A BATTERY ENERGY STORAGE SYSTEM

(71) Applicant: LG ENERGY SOLUTION, LTD., Seoul (KR)

(72) Inventors: Neill WHITE, Westborough, MA (US); Riddhi NARAYAN, Westborough, MA (US); Kiran KUMAR, Westborough, MA (US)

(21) Appl. No.: 19/042,713

(22) Filed: Jan. 31, 2025

Related U.S. Application Data
(60) Provisional application No. 63/549,068, filed on Feb. 2, 2024.

(51) Int. Cl. G01R 31/66; G01R 31/382; G06F 18/2415; H01M 10/42; H01M 10/48; H01M 50/204; H01M 50/251

(52) U.S. Cl. CPC G01R 31/66; G01R 31/382; G06F 18/2415; H01M 10/425; H01M 10/482; H01M 10/488; H01M 50/204; H01M 50/251; H01M 2010/4271; H01M 2010/4278; H01M 2220/10

(57) ABSTRACT

Systems and methods for detecting intermittent connections in a battery energy storage system (BESS) subsystem are disclosed. For each battery rack in the BESS subsystem, current time series data is received. A current rolling average is determined for each data point of the time series data by averaging current values of timestamps over a specified time interval. A current delta is determined for each data point, where the current delta is a difference between the current rolling average associated with the battery rack under analysis and a mean of the current rolling averages associated with the other battery racks in the BESS subsystem. A distribution profile of the current deltas is analyzed to detect a current anomaly at the respective battery rack. In response to detecting the current anomaly at the battery rack under analysis, an alert indicative of a faulty connection is displayed on a user interface.

### CROSS-REFERENCE TO RELATED APPLICATION

This application claims priority to and the benefit of U.S. Provisional Application 63/549,068 filed on Feb. 2, 2024, the disclosure of which is incorporated herein by reference.

### TECHNICAL FIELD

The present disclosure relates to managing a battery energy storage system (BESS), and more particularly to accurately detecting and mitigating faulty or intermittent connections in a BESS subsystem.

### BACKGROUND

BESSs have become a critical component in modern energy management systems. With the increasing integration of renewable electricity sources such as wind and solar, which are inherently intermittent, energy storage solutions are necessary to ensure electrical grid stability and efficient power distribution. BESS technology allows for the storage of excess electricity during periods of low demand and discharge of scarce electricity during high demand, thereby optimizing energy usage (by reducing the curtailment of solar and wind electricity), reducing reliance on fossil fuel-based power generation such as gas turbines, and mitigating the effects of climate change by reducing the release of greenhouse gases. This capability is particularly valuable as the global transition to cleaner energy sources accelerates, and as intermittent electricity sources gain larger shares of the electricity supply mix.

BESS subsystems (e.g., power blocks) comprise racks connected via a common DC-bus to manage power distribution. A critical issue arises when there are intermittent or loose connections in the DC-bus or the module-to-module (e.g., pack-to-pack) connections. Loose or intermittent connections may be caused by vibrations, repeated heating and cooling cycles, and/or corrosion, among other causes. These loose or intermittent connections can disadvantageously result in electrical arcing, localized overheating, melted insulation, and, in some cases, serious thermal events. These events result in significant operational disruptions, revenue loss, costly equipment replacements, and reduced system reliability. False positives in identifying loose connections can add further inefficiencies.

The background description provided herein is for the purpose of generally presenting context of the disclosure. Unless otherwise indicated herein, the materials described in this section are not prior art to the claims in this application and are not admitted to be prior art, or suggestions of the prior art, by inclusion in this section.

### SUMMARY

Accordingly, the present disclosure describes systems and methods that solve the aforementioned problems by detecting and mitigating intermittent connections in a BESS subsystem. The present systems and methods leverage a data-driven approach to detect anomalies in rack current profiles that differ from expected patterns within a BESS subsystem (e.g., a group of racks or a power block). By automating the detection of faulty or loose connections and generating alerts, the present systems and methods minimize revenue loss, prevent costly equipment damage, increase the lifespan of BESS components, and allow maintenance teams to identify and resolve issues before they escalate into critical failures or thermal events.

According to one aspect, the present disclosure is directed to a system for detecting and mitigating intermittent connections in a BESS subsystem comprising a plurality of battery racks connected to a common bus, comprising: a controller comprising one or more processing modules and one or more non-transitory memory storage modules storing computing instructions which when executed by the one or more processing modules is configured to, for each respective rack in the BESS subsystem: (a) receive current time series data divided into timestamps, wherein each of the timestamps corresponds to a current value; (b) determine a current rolling average for each respective data point of the time series data by averaging the current values of the timestamps over a specified time interval; (c) determine a current delta for each respective data point of the time series data, wherein the current delta is a difference between the current rolling average associated with the respective battery rack and a mean of the current rolling averages associated with the other battery racks in the BESS subsystem; (d) analyze a distribution profile of the current deltas to detect a current anomaly at the respective battery rack; and (e) in response to detecting the current anomaly at the respective battery rack; automatically disconnect or discharge the respective battery rack; and generate an alert indicative of a faulty or intermittent connection at the respective battery rack, wherein the alert includes a direction to perform an action to correct or mitigate the faulty or intermittent connection.

In some cases, analyzing the distribution profile to detect the current anomaly at the respective battery rack comprises: determine quantiles and spreads of quantiles of the distribution profile; and input the quantiles and the spreads of quantiles as features into a classifier to predict whether the respective battery rack has the current anomaly, where the respective battery rack is predicted as having the current anomaly based on comparisons of values in the quantiles and the spreads of quantiles of the distribution profile to one or more predefined current delta thresholds.

In some cases, the classifier comprises a random forest classifier, a support vector machine classifier, a gradient boosting machine classifier, or a logistic regression classifier.

In some cases, the classifier comprises the random forest classifier, and the comparisons of the values of the quantiles and the spreads of quantiles of the distribution profile to the one or more predefined current delta thresholds are performed at decision tree branch points in the random forest classifier.

In some cases, the controller is further configured to: select the predetermined current delta thresholds based on historical data patterns to reduce an occurrence of a false positive.

In some cases, the direction to perform an action to correct or mitigate the faulty or intermittent connection includes at least one of: inspecting module-to-module connections in the respective battery rack, inspecting a connection of the respective battery rack to the common bus, disconnecting the respective battery rack from the common bus, discharging the respective battery rack, ensuring fasteners at the respective battery rack are torqued to specification, replacing battery modules or packs at the respective battery rack, replacing connections at the respective battery rack, or activating an extinguishing fluid at the respective battery rack.

In some cases, the controller is further configured to: at least one of transmit the alert by at least one of email, SMS, or pager, or display the alert on a display, thereby mitigating potential damage to the battery energy storage system.

In some cases, the quantiles comprise a 1st quantile, 5th quantile, 10th quantile, a 25th quantile, a 75th quantile, a 90th quantile, a 95th quantile, or a 99th quantile.

In some cases, the spreads of quantiles comprise a spread of the 1st quantile and the 99th quantile, a spread of the 5th quantile and the 95th quantile, a spread of the 10th quantile and the 90th quantile, or a spread of the 25th quantile and the 75th quantile.

In some cases, steps (a)-(e) are performed for each battery rack in the BESS subsystem simultaneously.

In some cases, the BESS subsystem is configured to store renewable electricity generated by solar power or wind power in order to reduce reliance on fossil fuel-based power generation and mitigate climate change effects.

According to another aspect, the present disclosure is directed to a method for detecting and mitigating intermittent connections in a BESS subsystem comprising a plurality of battery racks connected to a common bus comprising, for each respective rack in the BESS subsystem: (a) receiving current time series data divided into timestamps, wherein each of the timestamps corresponds to a current value; (b) determining a current rolling average for each respective data point of the time series data by averaging the current values of the timestamps over a specified time interval; (c) determining a current delta for each respective data point of the plurality of data points of the current time series data, wherein the current delta is a difference between the current rolling average associated with the respective battery rack and a mean of the current rolling averages associated with the other battery racks in the BESS subsystem; (d) analyzing a distribution profile of the current deltas to detect a current anomaly at the respective battery rack; and (e) in response to detecting the current anomaly at the respective battery rack, generating an alert indicative of a faulty or intermittent connection at the respective battery rack, wherein the alert includes a direction to perform an action to correct or mitigate the faulty or intermittent connection, and displaying the alert on a user interface.

According to another aspect, the present disclosure is directed to a non-transitory computer-readable medium having computer-executable instructions stored thereon that, in response to execution by one or more processing modules of a controller, cause the controller to perform operations for detecting and mitigating intermittent connections in a BESS subsystem comprising a plurality of battery racks connected to a common bus, the operations comprising: (a) receiving current time series data divided into timestamps, wherein each of the timestamps corresponds to a current value; (b) determining a current rolling average for each respective data point of the time series data by averaging the current values of the timestamps over a specified time interval; (c) determining a current delta for each respective data point of the plurality of data points of the time series data, wherein the current delta is a difference between the current rolling average associated with the respective battery rack and a mean of the current rolling averages associated with the other battery racks in the BESS subsystem; (d) analyzing a distribution profile of the current deltas to detect a current anomaly at the respective battery rack; and (e) in response to detecting the current anomaly at the respective battery rack, generating an alert indicative of a faulty or intermittent connection at the respective battery rack, wherein the alert includes a direction to perform an action to correct or mitigate the faulty or intermittent connection, and displaying the alert on a user interface.

It should be noted that the technical effects obtainable through the present disclosure are not limited to the above-described effects, and other effects that are not mentioned herein will be clearly understood by those skilled in the art from the following descriptions.

### BRIEF DESCRIPTION OF THE DRAWINGS

The accompanying drawings illustrate exemplary aspects of the present disclosure and, together with the following detailed description, serve to provide further understanding of the technical spirit of the present disclosure. However, the present disclosure is not to be construed as being limited to the drawings.

FIG. 1 is a perspective view schematically showing the configuration of a battery container in accordance with an aspect of the present disclosure.

FIG. 2 is a perspective view schematically showing a form in which some components of the battery container are separated or moved according to in accordance with an aspect of the present disclosure.

FIG. 3 is a diagram showing the internal configuration of the battery container in accordance with an aspect of the present disclosure, viewed from above.

FIG. 4 is a schematic diagram showing a BESS subsystem comprising a power block in accordance with an aspect of the present disclosure.

FIG. 5 is a graph showing a divergent current profile in comparison to a normal current profile in accordance with an aspect of the present disclosure.

FIG. 6A is a graph showing the determination of a current delta for a data point of a current time series in accordance with an aspect of the present disclosure.

FIG. 6B is a graph showing the determination of current deltas for multiple data points of a current time series in accordance with an aspect of the present disclosure.

FIG. 6C shows the calculation of a current delta for a power block comprising four battery racks in accordance with an aspect of the present disclosure.

FIG. 7 is a graph showing a distribution profile of current deltas used to determine a current anomaly at a battery rack in accordance with an aspect of the present disclosure.

FIG. 8 is a table showing the distribution profile in accordance with an aspect of the present disclosure.

FIG. 9 is a flow chart showing a method for detecting and mitigating intermittent connections in a BESS subsystem in accordance with an aspect of the present disclosure.

FIG. 10 is a diagram showing a controller including a processor and memory in accordance with an aspect of the present disclosure.

### DETAILED DESCRIPTION OF THE DISCLOSURE

The present disclosure may be variously changed and have various aspects, and the specific aspects disclosed herein in detail are used to facilitate an understanding of the present disclosure to those skilled in the art.

Therefore, it should be understood that there is no intention to limit the present disclosure to the particular aspects disclosed, and on the contrary, the present disclosure covers all modifications, equivalents, and alternatives falling within the spirit and scope of the present disclosure.

In this application, it should be understood that terms such as “include” or “have” are intended to indicate the presence of a feature, number, step, operation, component, part, or a combination thereof described on the specification, and they do not preclude the possibility of the presence or addition of one or more other features or numbers, steps, operations, components, parts or combinations thereof.

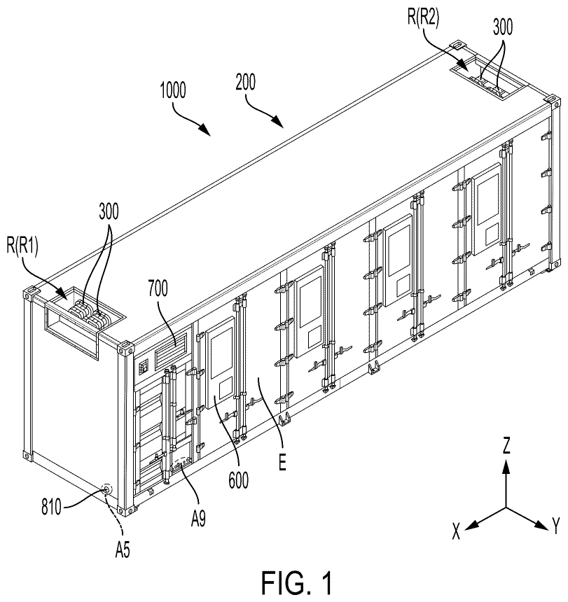

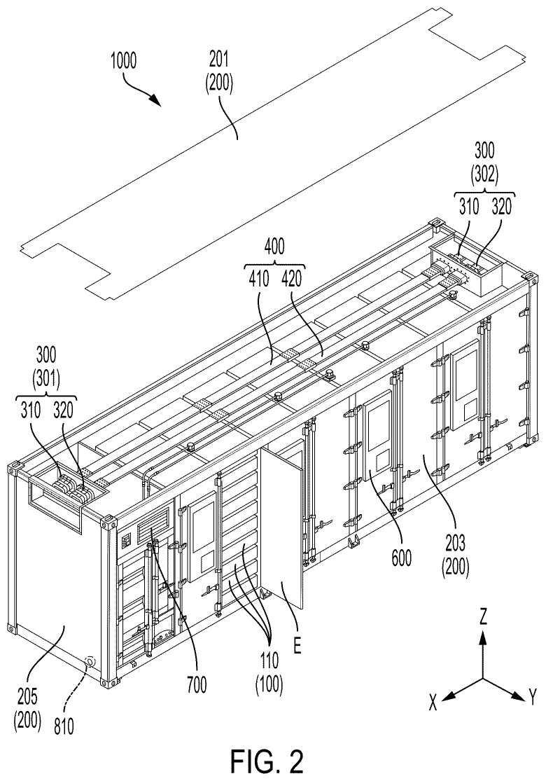

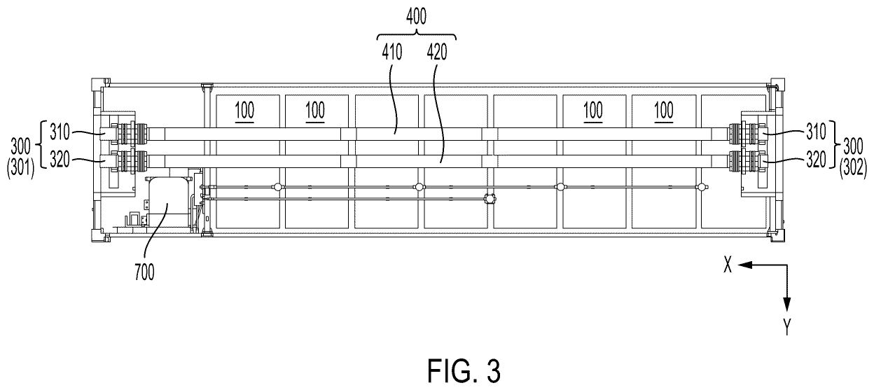

FIG. 1 is a perspective view schematically showing the configuration of a battery container 1000 according to an aspect of the present disclosure. Also, FIG. 2 is a perspective view schematically showing a form in which some components of the battery container 1000 are separated or moved according to an exemplary aspect of the present disclosure. FIG. 3 is a diagram showing the internal configuration of the battery container 1000 according to an aspect of the present disclosure, viewed from above.

Referring to FIGS. 1 to 3, a battery container 1000 according to the present disclosure includes a battery rack 100, a container housing 200, a main connector 300, and a main bus bar 400.

The battery rack 100 may include a plurality of battery modules 110. Here, each battery module 110 may be configured in a form in which a plurality of battery cells (secondary batteries) are accommodated in a module case. In addition, the battery modules 110 may be stacked in one direction, such as in an upper and lower direction, to form a battery rack 100. In particular, the battery rack 100 may include a rack case to facilitate stacking of the battery modules 110. In this case, a plurality of battery modules 110 may be accommodated in respective storage spaces provided in the rack case to form a module stack. In some aspects, the battery modules 110 may be arranged in other configurations, such as side-by-side or in a matrix pattern. The rack case may include features like cooling channels or structural reinforcements to support the weight of the stacked modules. In some cases, the battery rack 100 may incorporate sensors to monitor temperature, voltage, or other parameters of the battery modules 110.

The battery module 110 included in the battery rack 100 may further include a control unit such as a battery management system (BMS) for each group or certain groups. For example, a separate pack BMS may be provided for each battery module 110. In this case, each battery module 110 may be referred to as a battery pack. That is, it may be regarded that the battery rack 100 includes a plurality of battery packs. In various descriptions below, the battery module 110 may be replaced with a battery pack. In some cases, the battery rack 100 may incorporate sensors to monitor parameters like temperature, voltage, or current of the battery modules 110. The BMS for each battery module or pack may communicate with a higher-level rack BMS to coordinate overall rack performance and safety.

One or more battery racks 100 may be included in the battery container 1000. In particular, a plurality of battery racks 100 may be included in the battery container 1000. Also, the plurality of battery racks 100 may be disposed in at least one direction, for example, in a horizontal direction. For example, eight battery racks 100 may be included in the battery container 1000, and the plurality of battery racks 100 may be arranged in left and right directions (X-axis direction) inside the battery container 1000. When a plurality of battery racks 100 are included, a separate control unit, such as a rack BMS, may be provided for each battery rack 100. In this case, the rack BMS may be connected to the plurality of pack BMSs to exchange data and control the plurality of pack BMSs. Meanwhile, when the battery container 1000 includes at least one rack BMS, the rack BMS may be connected to a separate control device provided outside the battery container 1000, such as a control container. In addition, the control container may be connected to a rack BMS or a pack BMS of the battery container 1000 to control the same or exchange data with the same.

An empty space may be formed inside the container housing 200. Also, the container housing 200 may accommodate the battery rack 100 in the inner space. More specifically, the container housing 200 may be formed in a substantially rectangular parallelepiped shape, as shown in FIG. 1 and the like. In this case, the container housing 200 may include an upper housing 201, a lower housing (not-shown), a front housing 203, a rear housing (not shown), a left housing 205, and a right housing (not shown) around the inner space. Also, the container housing 200 may accommodate the battery rack 100 in the inner space defined by these six unit housings.

The container housing 200 may be made of a material that secures a sufficient level of rigidity to stably protects internal components from external physical and chemical factors. For example, the container housing 200 may be made of a metal material, such as steel, aluminum, titanium, or an alloy thereof, or may have such a metal material. In some aspects, the container housing 200 may be constructed from composite materials like carbon fiber reinforced polymers or fiberglass, which offer high strength-to-weight ratios. The housing may also incorporate corrosion-resistant alloys like stainless steel or galvanized steel in areas exposed to harsh environmental conditions. In some cases, the container housing 200 may utilize a combination of materials, such as a steel frame with aluminum panels, to balance strength, weight, and cost considerations. Additionally, the housing may include specialized coatings or treatments, such as powder coating or anodizing, to enhance durability and weather resistance.

The container housing may have a size identical or similar to the size of a shipping container. In addition, the container housing may follow the standards of a shipping container predetermined according to the ISO standards or the like. For example, the container housing may be designed with identical or similar dimensions as a 20-foot container or a 40-foot container. However, the size of the container housing may be appropriately designed depending on the situation. In particular, the size or shape of the container housing may be set variously according to the construction scale, shape, topography, or the like of a system to which the battery container is applied, such as an energy storage system. The present disclosure may not be limited by to the size or shape of the container housing. In some aspects, for example, the container housing may have other shapes such as cylindrical, spherical, or custom polygonal shapes. The housing may also be modular, allowing for expansion or contraction based on capacity needs. In some cases, the container housing may incorporate features like sloped roofs for water runoff or reinforced walls for increased durability in harsh environments.

The main connector 300 may be configured to be electrically connected to the outside. That is, with respect to the battery container 1000, the main connector 300 may be configured to be connected to another component outside the battery container 1000, for example another battery container 1000 or a control container equipped with a control unit such as a battery system controller (BSC).

The main connector 300 may be located on at least one side of the container housing 200. For example, the main connector 300 may be located on the left or right side of the container housing 200. Moreover, a plurality of main connectors 300 may be included in the battery container 1000. For example, as shown in FIGS. 2 and 3, the main connector 300 may include two main connectors 300, namely a first connector 301 and a second connector 302. The plurality of main connectors 300 may be located on different sides of the container housing 200. Moreover, the plurality of main connectors 300 may be located on opposite sides of the container housing 200. For example, as shown in FIGS. 1 to 3, the first connector 301 and the second connector 302 may be provided on the left and right sides of the container housing 200, respectively. In some aspects, the main connectors 300 may be located on the roof or floor of the container housing 200. In some cases, the main connectors 300 may be positioned at corners or edges of the container housing 200. The main connectors 300 may also be arranged in various configurations, such as in a staggered pattern or aligned vertically along the sides of the container housing 200. In some implementations, additional main connectors may be included on the front or back sides of the container housing 200 to provide further connection options.

The main bus bar 400 may be configured to transmit power. In particular, the main bus bar 400 may serve as a path through which a charging power and a discharging power for the battery rack 100 included in the corresponding battery container 1000 are transmitted. To this end, the main bus bar 400 may be electrically connected to each terminal of the battery module 110 provided in the battery rack 100. Also, the main bus bar 400 may be connected to the main connector 300. Accordingly, the main bus bar 400 may serve as a path through which a charging power is transferred from the main connector 300 to the battery module 110. In addition, the main bus bar 400 may serve as a path through which a discharging power is transmitted from the battery module 110 to the main connector 300.

Moreover, the main bus bar 400 may function as a power transmission line between the plurality of main connectors 300. To this end, different ends of the main bus bar 400 may be connected to different main connectors 300. For example, the main bus bar 400 may be a power line elongated in one direction, for example in left and right directions. In this case, both ends of the main bus bar 400 may be connected to different main connectors 300, for example the first connector 301 and the second connector 302. Also, the main bus bar 400 may serve as a path for transmitting power between different main connectors 300, for example between the first connector 301 and the second connector 302.

The main bus bar 400 may include two unit bus bars, namely a positive electrode bus bar 410 and a negative electrode bus bar 420, in order to function as a power transmission path. The positive electrode bus bar 410 may be connected to a positive electrode terminal of the battery rack 100 or a positive electrode terminal of the battery module 110 included therein. Also, the negative electrode bus bar 420 may be connected to a negative electrode terminal of the battery rack 100 or a negative electrode terminal of the battery module 110 included therein.

In addition, the main connector 300 may be separately provided at each end of the positive electrode bus bar 410 and the negative electrode bus bar 420. For example, the first connector 301 and the second connector 302 may be provided at the left and right ends of the positive electrode bus bar 410, respectively. The first connector 301 and the second connector 302 provided at both ends of the positive electrode bus bar 410 may be a positive electrode connector 310. Also, the first connector 301 and the second connector 302 may be provided at the left end and the right end of the negative electrode bus bar 420, respectively. The two connectors provided at both ends of the negative electrode bus bar 420, namely the first connector 301 and the second connector 302, may all be negative electrode connectors 320.

In addition, the battery container 1000 according to the present disclosure may include a cable cover CC. The cable cover CC may be configured to surround a cable connected to the battery container 1000. For example, a plurality of power cables may be connected to the terminal bus bar TB to transfer power. In this case, the cable cover CC may be located at one end, for example a lower end, of the terminal cover TC to protect a plurality of power cables connected to the terminal bus bar TB. Alternatively, the battery container 1000 may be connected to a data cable to exchange various data with other external components, such as a control container (not shown). In this case, the cable cover CC may be configured to protect data cables or the like connected to the battery container 1000 from the outside.

In particular, the cable cover CC may include a cable tray CC1 and a tray cover CC2. The cable tray CC1 may include a body portion attached to an outer wall of the container housing 200 and a sidewall portion protruding outward from an edge of the body portion. For example, the sidewall portion may be formed to protrude to the left from the front edge and the rear edge of the body portion. The tray cover CC2 may be coupled to the end of the sidewall portion protruding from the body portion of the cable tray CC1 to form an empty space therein together with the body portion and the sidewall portion. In particular, this empty space may be formed in a hollow shape. Accordingly, the cable may extend outward from the battery container 1000 through the empty space of the cable cover CC. In addition, the cable extending to the outside may be connected to other external components, such as the control container (not shown) or another battery container 1000.

According to this aspect, by minimizing the exposure of the cable extending from the battery container 1000 to the outside, it is possible to protect the cable and prevent damage or breakage of the cable. Moreover, the cable cover CC is configured to have a hollow formed downward at the side surface of the container housing, so that the cable accommodated inside may be exposed downward to the outside. In this case, it may be advantageous for installation, management, and undergrounding of the cable.

In addition, the battery container 1000 according to the present disclosure may further include an air conditioning module 600 as shown in FIGS. 1 and 2. The air conditioning module 600 may be configured to regulate air inside the container housing 200. In particular, the air conditioning module 600 may control the temperature state of an internal air. Moreover, the air conditioning module 600 may be configured to circulate air inside the container housing 200 to control the temperature of various electronic equipment such as the battery rack 100 or the rack BMS included in the battery container 1000 within a certain range. In particular, the air conditioning module 600 may cool the air inside the container housing 200. For example, the air conditioning module 600 may be configured to absorb heat from the air inside the container housing 200 and discharge the heat to the outside. In addition, the air conditioning module 600 may be configured to remove dust or foreign substances from the air inside the container housing 200.

Representatively, the air conditioning module 600 may include at least one HVAC (Heating, Ventilation, & Air Conditioning). For example, the battery container 1000 according to the present disclosure may include four HVACs. The HVAC may allow air to circulate inside the container housing 200. In this case, the temperature of the battery rack 100 may be lowered, and a temperature difference between the battery racks 100 included in the container housing 200 or between the battery modules 110 may be reduced.

In particular, the container housing 200 may include at least one door, as indicated by E in FIGS. 1 and 2, to facilitate installation, maintenance, or repair of the battery rack 100. For example, the container housing 200 may have eight doors E on the front side. Also, two doors E may be opened and closed as a pair in a casement form. In addition, such a door E may be additionally provided on another part of the container housing 200, for example at the rear surface.

In this way, when the door E is provided to the container housing 200, the HVAC may be installed in the door E of the container housing 200. For example, when two doors E are configured as a pair, the HVAC may be provided to one of the two doors E. In addition, the HVAC, namely the air conditioning module 600, may be configured to penetrate the container housing 200, particularly the door E. In this case, one surface of the air conditioning module 600 may be exposed to the outside of the container housing 200, and the other surface of the air conditioning module 600 may be exposed to the inside of the container housing 200. Accordingly, the inner surface of the air conditioning module 600 may contact the internal air of the container housing 200 to absorb heat, and the outer surface of the air conditioning module 600 may contact the external air of the container housing 200 to discharge heat.

The air conditioning module 600 may be configured to prevent direct contact between internal air and external air. That is, the air conditioning module 600 may be configured to prevent internal air from being discharged to the outside and to prevent external air from being introduced into the inside. Therefore, even if the temperature inside the container housing 200 rises, the air conditioning module 600 may absorb only heat from the internal air and discharge the heat to the outside without directly discharging the internal air to the outside. According to this aspect, even if a fire or toxic gas is generated inside the battery container 1000, it is possible to prevent the fire or toxic gas from being discharged to the outside and causing damage to other devices such as other nearby battery containers 1000 or workers at the outside.

In addition, the battery container 1000 according to the present disclosure may further include a venting module 700 as shown in FIGS. 1 and 2. The venting module 700 may be configured to discharge gas inside the container housing 200 to the outside. In addition, the venting module 700 may introduce an external air of the container housing 200 into the inside. Accordingly, the venting module 700 may function as a ventilation device. That is, the venting module 700 may exchange or circulate gas between the inside and the outside of the container housing 200.

In particular, the venting module 700 may be configured to operate in an abnormal situation, such as when a venting gas or fire is generated in a specific battery module 110. Moreover, the venting module 700 may be configured to discharge gas to the outside when the gas or the like is generated inside the container housing 200 due to a thermal runaway phenomenon or the like of the battery rack 100. Moreover, the venting module 700 may be configured to be in a closed state in a normal state and be switched to an open state in an abnormal state such as a thermal runaway situation. In this case, since the venting module 700 performs active ventilation, the venting module 700 may be referred to as an AVS (Active Ventilation System) or include such a system.

In this case, it is possible to prevent a larger problem such as an explosion from occurring due to an increase in the internal pressure of the battery container 1000. In addition, in this case, by rapidly discharging a combustible gas inside the container housing 200 to the outside, it is possible to lower the possibility of a fire in the battery container 1000 or delay the occurrence of a fire, and the scale of a fire may be reduced.

Meanwhile, in the aspect where both the venting module 700 and the air conditioning module 600 are included, in a normal situation, the venting module 700 may not operate, but the air conditioning module 600 may operate. In this case, in the process of cooling, it is possible to prevent foreign substances or moisture from flowing into the container housing 200 through the venting module 700. According to this aspect, since the air conditioning module 600, the venting module 700, and the like are included in the battery container 1000, just by transporting and installing the battery container 1000, the air conditioning module 600 or the venting module 700 may be transported and installed together. Therefore, on-site installation work for installing the energy storage system may be minimized, and the connection structure may be simplified.

In this aspect, the air conditioning module 600 and/or the venting module 700 may operate under the control of the control container (not shown). Alternatively, the air conditioning module 600 and/or the venting module 700 may be controlled by a control unit included in the battery container 1000, such as a rack BMS that controls the charge/discharge operation of each battery rack 100 or another separate control unit.

In addition, the battery container 1000 according to the present disclosure may include at least one sensor and provide sensing information to the rack BMS included in the battery container 1000, another separate control unit, or the control container (not shown). For example, a temperature sensor, a smoke sensor, an H₂ sensor, and/or a CO sensor may be included in the battery container 1000. In this case, the operation of the air conditioning module 600 and/or the venting module 700 may be controlled based on the information sensed by these sensors. The battery container 1000 may further include a firefighting connector 810 to a firefighting module (not shown).

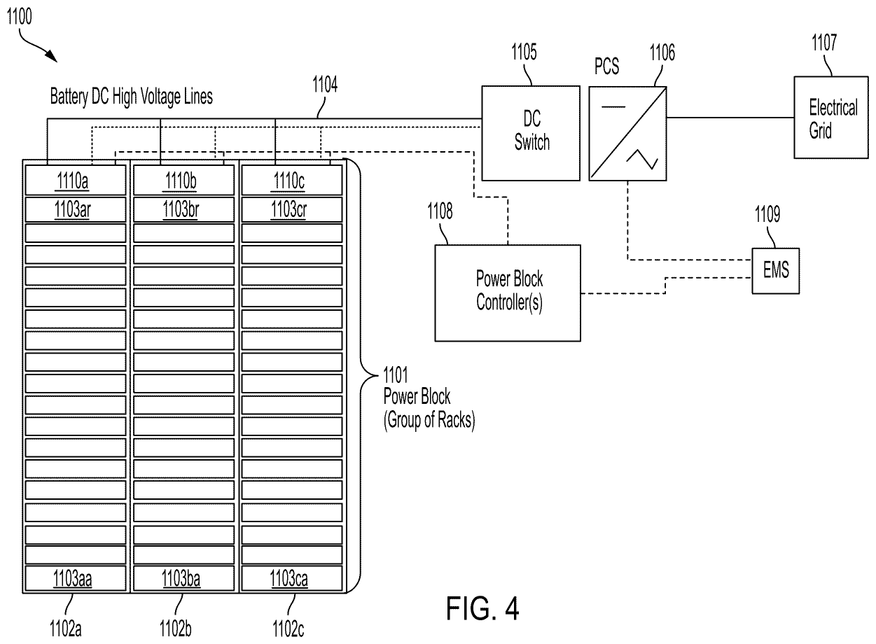

FIG. 4 is a diagram showing a BESS subsystem 1100 in accordance with an aspect of the present disclosure. The BESS subsystem 1100 may include a power block 1101 comprising a plurality of battery racks 1102a, 1102b and 1102c, which in turn respectively comprise a plurality of battery packs 1103aa-ar, 1103ba-br, and 1103ca-cr, and battery protection units (BPUs) 1110a, 1110b and 1110c. The racks 1102a-c may comprise physical structures with a standardized form (e.g., a steel or aluminum frame), allowing for easy installation, management, and scalability. A suitable exemplary battery rack may be, for example, the TR1300 (Model ERT5422CN201) manufactured by LG Energy Solution. In some aspects, the racks may be constructed from other materials such as carbon fiber composites, fiberglass, or reinforced plastics to reduce weight while maintaining strength. Each of the battery packs 1103aa-ar, 1103ba-br, and 1103ca-cr may comprise one or more battery modules, and may be connected to monitoring and management electronics such as a battery management system (BMS). Each of the battery modules may comprise a plurality of battery cells connected together, which may be encased and managed as a single unit. The battery cells are the smallest unit of the BESS, where the electrochemical reaction occurs to store and release energy. The cells may have different form factors, such as cylindrical, pouch, or prismatic. In each of the battery racks 1102a-c, the battery packs 1103aa-ar, 1103ba-br and 1103ca-cr may be electrically connected in series with respect to each other, although the present disclosure is not limited thereto. The battery racks 1102a-c may be electrically connected in parallel with respect to each other, although the present disclosure is not limited thereto. The battery racks 1102a-c and battery packs 1103aa-ar, 1103ba-br and 1103ca-cr may be connected in any series or parallel arrangement to achieve a target power output. While battery packs and/or modules are described in this particular aspect, other racks that exclude packs and/or modules are contemplated within the scope of this disclosure. For example, the rack may comprise a plurality of battery cells, without any module.

The BPUs 1110a-c, which may be referred to as rack BMSs, include electrical and communication interfaces that connect to the packs 1103aa-ar, 1103ba-br and 1103ca-cr within each respective rack 1102a, 1102b and 1102c. BPUs 1110a-c may be electrically and communicationally connected to the voltage lines 1104 and one or more power block controllers 1108. In some cases, the BPUs 1110a-c may be located in respective controller containers separate from the containers of the racks 1102a-1102c.

The battery racks 1102a-c may be electrically connected to an electrical grid 1107 via voltage lines 1104. The DC switch 1105 may be used to disconnect or isolate the battery from other components for maintenance, safety, or in the event of a fault, particularly from the power conversion system (PCS) 1106, or grid-tied inverter. In the case of an overvoltage, overcurrent, or other fault in the system, the DC switch 1105 may quickly interrupt the current to prevent damage to the power block 1101 or other components. The PCS 1106 manages the conversion between DC power from the power block 1101 and AC power for use by the electrical grid 1107 (i.e., the load). The PCS 1106 may include both an inverter (DC to AC) and a rectifier (AC to DC), enabling bidirectional energy flow between the power block 1101 and the electrical grid 1107. The PCS 1106 synchronizes the output from the power block 1101 with the voltage, frequency, and phase of the grid 1107, allowing the power block 1101 to smoothly inject electricity into the grid 1107 or absorb electricity from the grid 1107.

The energy management system (EMS) 1109 may coordinate and optimize the overall energy flows in the BESS subsystem 1100. The EMS 1109 may handle the strategic decisions of when and how energy should be stored or discharged, and may integrate multiple energy resources (for example, co-located solar and wind electricity connected in a microgrid and/or the grid 1107). The EMS 1109 may decide when the BESS subsystem 1100 should store or discharge electricity based on load demands, market signals (e.g., electricity prices such as locational marginal prices (LMP)), and the availability of renewable electricity, and may manage the interaction between the power block 1101 and the grid 1107, providing services such as frequency regulation, voltage support, demand response.

The power block controller (PBC) 1108 may control and operate individual components within the BESS subsystem 1100, such as the battery packs 1103aa-ar, 1103ba-br and 1103ca-cr and the battery modules and cells therein, and ensures the safe and efficient operation of the BESS subsystem 1100 at the hardware level. The PBC 1108 may work in conjunction with one or more BMSs to ensure safe operation of the battery cells, preventing overcharging, deep discharging, or temperature issues. In coordination with the EMS 1109, the PBC 1108 may manage the conversion of DC power from the power block 1101 into AC power for the grid 1107 and vice versa (coordinating with the EMS to follow power setpoints) and may make adjustments in real time ensure that the power output from the PB 1101 meets the voltage and frequency requirements of the grid 1107. The PBC 1108 may monitor the power block 1101 for faults and execute protective mechanisms in response to issues such as overvoltage, overcurrent, or overheating, for example, in conjunction with the DC switch 1105. The PBC 1108 may be responsible for executing commands from the EMS 1109 at the hardware level.

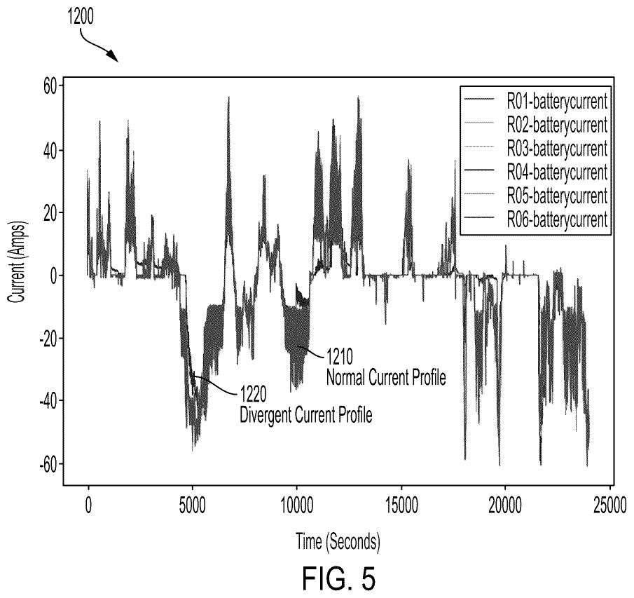

FIG. 5 is a graph 1200 showing a divergent current profile 1220 of a battery rack (e.g., one of the battery racks 1102a-c) in comparison to a normal current profile 1210 of a battery rack in accordance with an aspect of the present disclosure. When racks are connected to the same DC bus, all connected racks are expected to show the same current signal profile with minor variations. Any difference in the current signal between racks may help to identify potential issues. The divergent current profile 1220 may indicate a loose or intermittent connection in the current path, for example, at the DC bus connection or between packs or modules within the rack. Such anomalies can lead to further deterioration of the connection, resulting in heat spots or electrical arcing. Detecting and addressing these issues early can prevent equipment failure, improve system reliability, and reduce maintenance and replacement costs.

In some cases, rack currents may vary for reasons not related to a loose or intermittent connection, for example, transitioning from the current equalization phase to connected status which may indicate a false positive. When a battery rack is initially connected to the DC bus, the internal current may differ from that of other racks in the zone. This difference arises due to variations in rack charge levels, internal resistance, or operating states. During the current equalization phase, the rack adjusts its current flow to balance with the DC bus. This process may involve transient spikes or dips in current as the rack aligns with the overall current profile of the BESS subsystem. After the current equalization phase, the rack achieves a steady state where the current is consistent with other racks connected to the DC bus. In this state, all racks in the BESS subsystem exhibit a uniform current profile with minor expected variations, ensuring smooth power delivery and load balancing across the system.

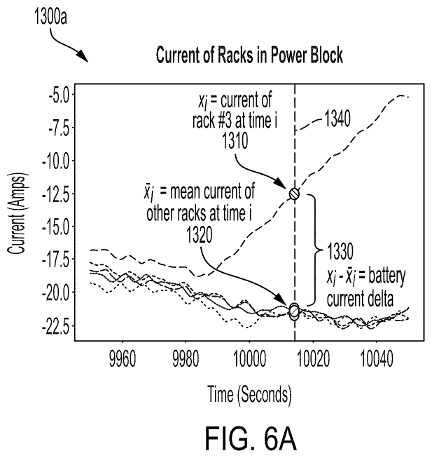

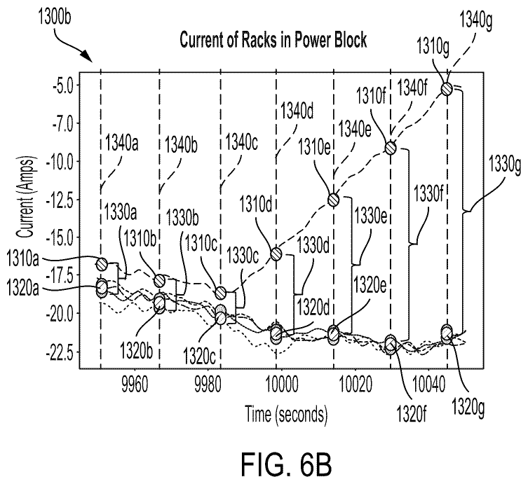

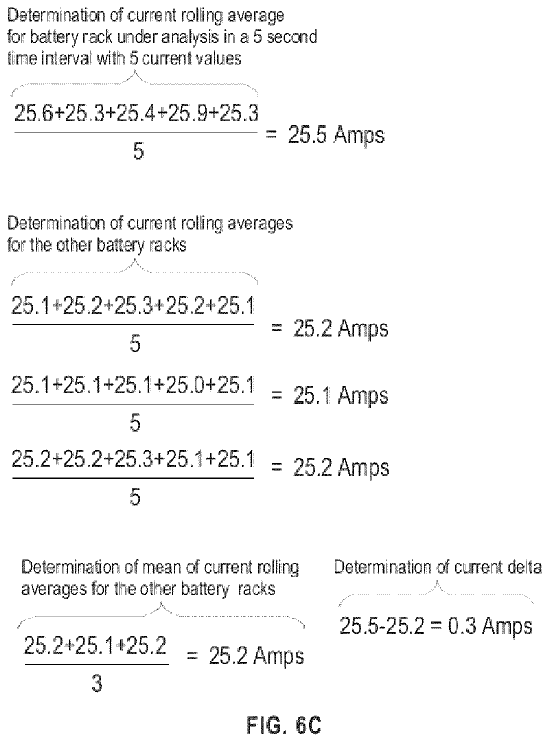

FIG. 6A is a graph 1300a showing the determination of a current delta 1330 for a data point 1340 of a current time series in accordance with an aspect of the present disclosure. The current time series may include current data measured for each rack in a BESS subsystem (e.g., the power block 1101 shown in FIG. 4). The current time series may be divided into a plurality of timestamps, where each of the timestamps corresponds to a current value. In some cases, the sampling rate is 1 second, so that the current is measured every second and each timestamp is separated by 1 second, although the present disclosure is not limited thereto, and the sampling rate may be every 0.1, 0.2, 0.3, 0.4, 0.5, 0.6, 0.7, 0.8, 0.9, 1, 1.5, 2.0, 2.5, 3, 3.5, 4, 4.5 or 5 seconds, and so on.

In some cases, the current delta 1330 may be determined as the difference (i.e., x̅,xᵢ) between the current 1310 (xᵢ) of a rack under analysis (e.g., rack #3 of a BESS subsystem) at the timestamp i of the data point 1340 and a mean of currents 1320 (x̅ᵢ) of other racks (e.g., the other racks 1, 2 4 and 5 of the BESS subsystem) at the timestamp i of the data point 1340. In some cases, the current delta 1330 is recorded as an absolute value.

FIG. 6B is a graph 1300b showing the determination of multiple current deltas 1330a-g for multiple data points 1340a-g of a current time series in accordance with an aspect of the present disclosure.

In some cases, instead of determining a difference between a current of the rack under analysis and a mean of currents of the other racks (as described with respect to FIG. 6A), a difference may be calculated between current rolling averages 1310a-g and respective means 1320a-g of current rolling averages. Calculating the current deltas 1330a-g using rolling averages removes spurious or transient variations (e.g., noise or inaccurate current measurements), ensuring that the calculation of the current deltas 1330a-g focuses on persistent deviations indicative of actual current anomalies.

For example, at the data point 1340b, the current rolling average 1310b for the rack under analysis may be determined by averaging the current values corresponding to the timestamps in a specified time interval, which may be configurable. For example, if the time interval is 10 seconds and each timestamp is separated by one second, then 10 current values are averaged to calculate the current rolling average 1310b. In some cases, the time interval is about 1, 2, 3, 4, 5, 6, 7, 8, 9, 10, 11, 12, 13, 14, 15, 20, 25, 30, 45, 60, 75, or 100 seconds, although the present disclosure is not limited thereto.

In addition to calculating the respective current rolling averages 1310a-g for the battery rack under analysis at each of the data points 1340a-g, the respective current rolling averages for the other battery racks may be calculated for each of the data points 1340a-g, which are then used to calculate respective means 1320a-g of current rolling averages. The current deltas 1330a-g may then be respectively determined by calculating the difference between the current rolling averages 1310a-g and the means 1320a-g of current rolling averages. For example, FIG. 6C shows the calculation of a current delta for a power block comprising four battery racks.

In some cases, current rolling medians may be calculated instead of current rolling averages for each of the battery racks at the data points 1340a-g. In some cases, one or more of the timestamps corresponds to a data point 1340a-g.

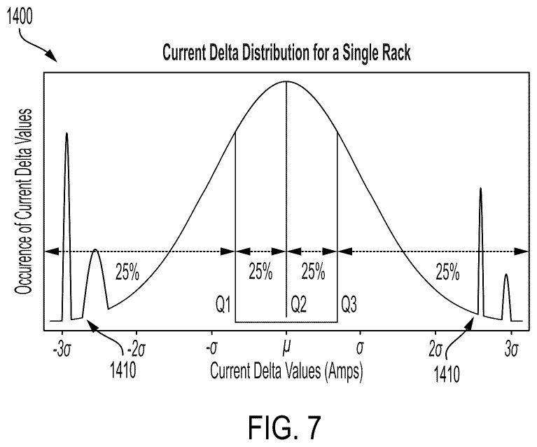

FIG. 7 is a graph 1400 showing a distribution profile of current deltas used to determine a current anomaly at a battery rack under analysis, in accordance with an aspect of the present disclosure. The distribution profile may be analyzed to detect a current anomaly by determining quantiles and spreads of quantiles of the distribution profile. As shown in FIG. 7, the distribution profile shows non-negligible peaks 1410 at the edges, which may indicate a current anomaly and a faulty or intermittent connection.

A quantile divides the distribution profile into equal-sized portions based on the data's distribution. For example, the 25th quantile (Q1) represents the values below which 25% of the data lies, while the 75th quantile (Q3) represents the values below which 75% of the data lies. A spread of quantiles measures the range between two quantiles. For example, the interquartile range (IQR) is the spread between the 25th and 75th quantiles (Q3-Q1), and represents the values of the middle 50% of the data.

In some cases, the quantiles may comprise a 1st quantile, 5th quantile, 10th quantile, a 25th quantile, a 75th quantile, a 90th quantile, a 95th quantile, or a 99th quantile.

In some cases, the spreads of quantiles may comprise a spread of the 1st quantile and the 99th quantile, a spread of the 5th quantile and the 95th quantile, a spread of the 10th quantile and the 90th quantile, or a spread of the 25th quantile and the 75th quantile.

The quantiles and the spreads of quantiles may be input as features into a classifier to predict whether the battery rack under analysis has the current anomaly. The battery rack under analysis is predicted as having the current anomaly based on comparisons of values (e.g., occurrences of current deltas) in the quantiles and the spreads of quantiles to one or more predefined current delta thresholds, which may be configurable. For example, if the values in a quantile exceed a predefined current delta threshold, that may indicate the presence of a current anomaly in the rack under analysis.

In some cases, the classifier comprises a random forest classifier, which may combine multiple decision trees to make predictions. Each decision tree may be trained on a random subset of the features, and learns to classify data points (e.g., as “intermittent connection” or “not intermittent connection”) by splitting the data at each node based on thresholds. The random forest may make a final prediction by aggregating the results of all the trees-typically through majority voting for classification tasks. In some cases, the comparisons of the values of the quantiles and the spreads of quantiles of the distribution profile to the one or more predefined current delta thresholds are performed at decision tree branch points in the random forest classifier. In some cases, the classifier comprises a support vector machine classifier, a gradient boosting machine classifier, or a logistic regression classifier.

The values in the quantiles and spreads of quantiles, and the values of the one or more predefined current delta thresholds, may depend on the size of the current time series data file, the number of timestamps, and the number of data points. In some cases, the values of the one or more predefined current thresholds are greater than or equal to 1 determined current delta and less than or equal to 100,000,000,000 determined current deltas in the quantile or spread of quantiles, although the present disclosure is not limited thereto.

Very small and very large current deltas (e.g., the 99.9th quantile) are often not indicative of faulty or intermittent connection problems, and may therefore be disregarded. Thus, according to aspects of this disclosure, it may be beneficial to select metrics that detect current anomalies without being prone to false positives (e.g., equalization events). In some cases, the threshold is selected based on historical data patterns (e.g., using logistic regression, machine learning, or other supervised algorithm) to reduce the occurrence of false positives.

In response to detecting the current anomaly, an alert indicative of a faulty or intermittent connection at the respective battery rack may be generated, thereby mitigating potential damage to the battery energy storage system. The alert may comprise information identifying the respective battery rack and a timeframe of the detected current anomaly, and may be transmitted by email, SMS, or pager, or other notification to a site operator of the BESS (for example, to a computing device, cell phone, or pager of a site operator). In some cases, the alert may be displayed on a display or screen (e.g., an LCD monitor connected to a site controller).

In some cases, the alert includes a direction to perform an action to correct or mitigate the faulty or intermittent connection.

For example, the action may include at least one of: inspecting module-to-module connections in the battery rack under analysis (for example, connections between the battery modules 110 described with respect to FIGS. 1-3), inspecting a connection of the battery rack under analysis to the common bus (for example, the main connector 300 described with respect to FIGS. 1-3), disconnecting the battery rack under analysis from the common bus, discharging the battery rack under analysis, ensuring fasteners at the battery rack under analysis are torqued to specification, replacing battery modules or packs at the battery rack under analysis, replacing connections at the battery rack under analysis, or activating an extinguishing fluid at the battery rack under analysis.

In some cases, the corrective action may be automated so that it is performed automatically. For example, the controller may be configured to automatically disconnect the respective battery rack from the common bus upon detecting the current anomaly. The controller may also be programmed to automatically initiate a discharge sequence for the affected battery rack. Additionally, the system may include automated fastener torque checking devices that can be activated by the controller remotely to ensure connections are properly secured. In some implementations, the controller may activate automated replacement systems to swap out faulty modules or packs. The system may also incorporate automated fire suppression mechanisms that can be remotely activated by the controller to dispense extinguishing fluid if thermal events are detected in conjunction with the current anomaly. In some cases, the corrective action may be performed manually (e.g., by one or more members of a maintenance team).

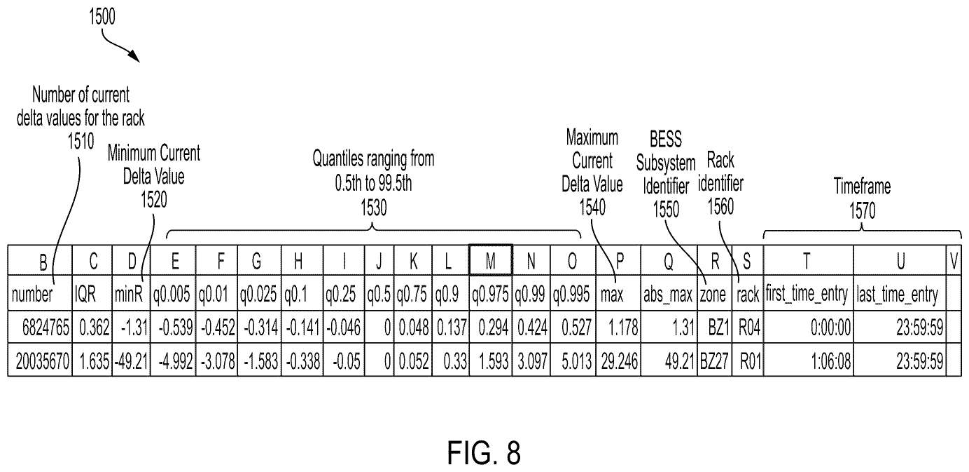

FIG. 8 is a table 1500 showing an example of a distribution profile of current deltas, in accordance with an aspect of the present disclosure. The table may include columns showing, for each battery rack, the number of current deltas 1510, the minimum current delta value 1520, the quantiles 1530 (e.g., ranging from 0.5th to 99.5th), the maximum current delta value 1540, the BESS subsystem identifier 1550, the rack identifier 1560, and the timeframe 1570 of the current time series. The first time entry of the timeframe 1570 may be recorded at the point of determining the minimum current delta value 1520 for the rack under analysis, and the last time entry of the timeframe 1570 may be recorded at the point of determining the maximum current delta 1540 for the rack under analysis (for example, during a one-day period).

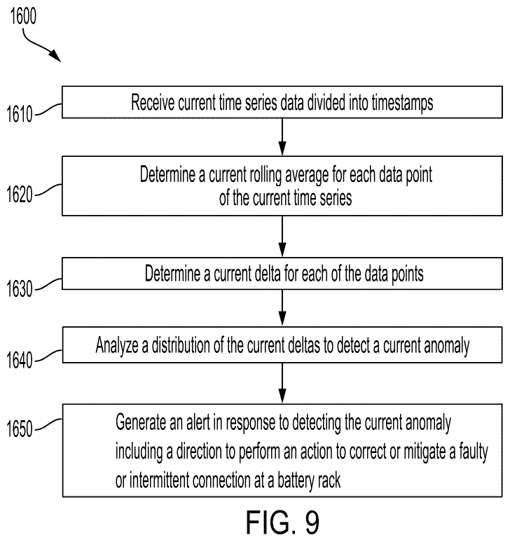

FIG. 9 is a flow chart 1600 showing a method for detecting and mitigating intermittent connections in a BESS subsystem in accordance with an aspect of the present disclosure. The method may be performed for one or more battery racks in a BESS subsystem (e.g., a power block or group of battery racks). In some cases, the steps 1610-1660 may be performed simultaneously.

At step 1610, current time series data for a respective battery rack is received. The current time series data may be divided into timestamps, where each of the timestamps corresponds to a current value. For example, each time stamp may be separated by 1 second.

At step 1620, a current rolling average may be determined for each data point of the time series data by averaging the current values of the timestamps over a specified time interval. For example, the time interval may be 30 seconds, in which case 30 current values may be averaged to determine the current rolling average.

At step 1630, a current delta may be determined for each data point of the current time series data, where the current delta is a difference between the current rolling average associated with the respective battery rack and a mean of the current rolling averages associated with the other battery racks in the BESS subsystem.

At step 1640, a distribution profile of the current deltas may be analyzed to detect a current anomaly.

At step 1650, in response to detecting the current anomaly, an alert indicative of a faulty or intermittent connection at the respective battery rack may be generated. The alert may include a direction to perform an action to correct or mitigate the faulty or intermittent connection.

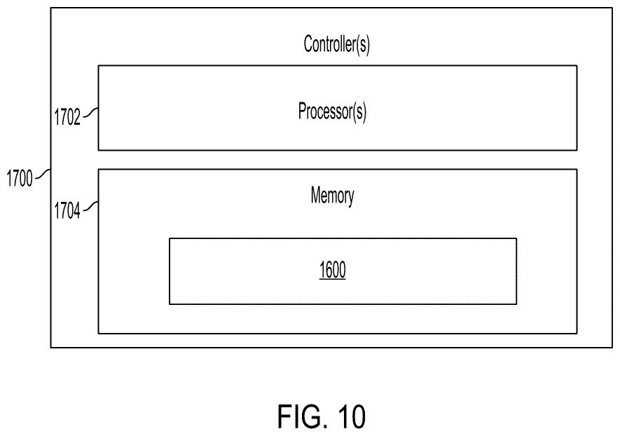

FIG. 10 is a schematic diagram illustrating a controller 1700 implementing the present systems and/or methods, for example, the method described with respect to the flow chart 1600 of FIG. 9, according to an aspect of the present disclosure.

The controller 1700 may include one or more processors 1702 (i.e., processing modules) configured to execute program instructions maintained on a memory 1704 (i.e., memory modules). In this regard, the one or more processors 1702 of controller 1700 may execute any of the various methods, processes, steps, or algorithms described throughout the present disclosure, for example, the steps 1610-1650 of the flow chart 1600 described with respect to FIG. 9. Further, the controller 1700 may be configured to receive data including, but not limited to current time series data (for example, from the PBC 1108 or the EMS 1109 described with respect to FIG. 4).

The controller 1700 (i.e., computing device) may comprise a desktop computer, mainframe computer system, workstation, server computer, image computer, parallel processor, mobile device, tablet, headset, wearable computer, or any other computer system (e.g., networked computer). The one or more processors 1702 of the controller 1700 may include any processing element known in the art. In this sense, the one or more processors 1702 may include any microprocessor-type device configured to execute algorithms and/or instructions, for example, application specific integrated circuit (ASIC), field programmable gate array (FPGA), parallel processor, graphics processing unit (GPU), central processing unit (CPU), microcontroller units (MCUs), digital signal processors (DSPs), system-on-chip (SoC) processors, programmable logic controllers (PLCs), a logical circuit, an electronic processor, or other chipsets. It is further recognized that the term “processor” may be broadly defined to encompass any device having one or more processing elements, which execute program instructions from a non-transitory memory 1704. Further, the steps described throughout the present disclosure may be performed by a single controller 1700 or, alternatively, multiple controllers. For example, the power block controller 1108, EMS 1109, PCS 1106 and controller 1700 may be the same controller or multiple controllers. Additionally, the controller 1700 may include one or more controllers housed in a common housing or within multiple housings. In this way, any controller or combination of controllers may be separately packaged as a module suitable for integration into BESS subsystem 1100.

The memory 1704 may include any storage medium known in the art suitable for storing program instructions executable by the associated one or more processors 1702. For example, the memory 1704 may include a non-transitory memory medium. By way of another example, the memory 1704 may include, but is not limited to, a read-only memory, a random access memory, a magnetic or optical memory device (e.g., disk), a magnetic tape, a solid state drive, etc. It is further noted that memory 1704 may be housed in a common controller housing with the processor(s) 1702. In some cases, the memory 1704 may be located remotely with respect to the physical location of the processors 1702 and controller 1700. For instance, the one or more processors 1702 of controller 1700 may access a remote memory (e.g., server or cloud), accessible through a network (e.g., internet, intranet and the like).

The systems and/or methods of the present disclosure may be implemented as computer programs stored in the memory 1704. Any of the data, information, metrics, figures, statistics, inputs, outputs, values, variables or parameters described in the present disclosure may be stored in the memory 1704. A computer program (also known as a program, program instructions, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one controller or on multiple controllers that are located at one site or distributed across multiple sites and interconnected by a communication network.

To provide for interaction with a user, embodiments of the subject matter described in this specification may be displayed on a user interface (UI), such as a display device, e.g., a CRT (cathode ray tube), LCD (liquid crystal display), LED (light-emitting diode), OLED (organic light-emitting diode), micro-LED, mini-LED, plasma, DLP (Digital Light Processing), QLED (Quantum dot LED), or e-ink monitor for displaying information to the user. An input device such as a keyboard and/or a pointing device (e.g., a mouse, touchpad, touchscreen, capacitive touchscreen, resistive touchscreen, stylus, digital pen, game controller, joypad, joystick, gamepad, remote control, gesture control device, eye-tracking device, facial recognition system, and/or a trackball, may be used to provide input to the computer. Input may also be provided through wearable devices such as smart glasses, smart watches, VR and/or AR goggles, rings, or other body-worn sensors. While visual or graphical user interfaces are described here, the disclosure contemplates screen readers or voice-controlled systems and other auditory systems as user interfaces, including natural language processing systems, voice recognition systems, and/or text-to-speech systems. The system may also support multimodal interaction combining two or more input methods simultaneously or sequentially, such as touch input combined with gesture control.

In the above, the present disclosure has been described in more detail through the drawings and aspects. However, the configurations described in the drawings or the aspects in the specification are merely aspects of the present disclosure and do not represent all the technical ideas of the present disclosure. Thus, it is to be understood that there may be various equivalents and variations in place of them at the time of filing the present application which are encompassed by the claims.

What is claimed is:

1. A system for detecting and mitigating intermittent connections in a battery energy storage system (BESS) subsystem comprising a plurality of battery racks connected to a common bus, comprising:
a controller comprising one or more processing modules and one or more non-transitory memory storage modules storing computing instructions which when executed by the one or more processing modules is configured to, for each respective rack in the BESS subsystem:
(a) receive current time series data divided into timestamps, wherein each of the timestamps corresponds to a current value;
(b) determine a current rolling average for each respective data point of the time series data by averaging the current values of the timestamps over a specified time interval;
(c) determine a current delta for each respective data point of the time series data, wherein the current delta is a difference between the current rolling average associated with the respective battery rack and a mean of the current rolling averages associated with the other battery racks in the BESS subsystem;
(d) analyze a distribution profile of the current deltas to detect a current anomaly at the respective battery rack; and
(e) in response to detecting the current anomaly at the respective battery rack;
automatically disconnect or discharge the respective battery rack; and
generate an alert indicative of a faulty or intermittent connection at the respective battery rack, wherein the alert includes a direction to perform an action to correct or mitigate the faulty or intermittent connection.

2. The system of claim 1, wherein analyzing the distribution profile to detect the current anomaly at the respective battery rack comprises:
determine quantiles and spreads of quantiles of the distribution profile; and
input the quantiles and the spreads of quantiles as features into a classifier to predict whether the respective battery rack has the current anomaly;
wherein the respective battery rack is predicted as having the current anomaly based on comparisons of values in the quantiles and the spreads of quantiles of the distribution profile to predefined current delta thresholds.

3. The system of claim 2, wherein the classifier comprises a random forest classifier, a support vector machine classifier, a gradient boosting machine classifier, or a logistic regression classifier.

4. The system of claim 3, wherein the classifier comprises the random forest classifier, and the comparisons of the values of the quantiles and the spreads of quantiles of the distribution profile to the predefined current delta thresholds are performed at decision tree branch points in the random forest classifier.

5. The system of claim 2, wherein the controller is further configured to: select the predetermined current delta thresholds based on historical data patterns to reduce an occurrence of a false positive.

6. The system of claim 1, wherein the direction to perform an action to correct or mitigate the faulty or intermittent connection includes at least one of: inspecting module-to-module connections in the respective battery rack, inspecting a connection of the respective battery rack to the common bus, ensuring fasteners at the respective battery rack are torqued to specification, replacing battery modules or packs at the respective battery rack, replacing connections at the respective battery rack, or activating an extinguishing fluid at the respective battery rack.

7. The system of claim 1, wherein the controller is further configured to: at least one of transmit the alert by at least one of email, SMS, or pager, or display the alert on a user interface, thereby mitigating potential damage to the battery energy storage system.

8. The system of claim 1, wherein the quantiles comprise a 1st quantile, 5th quantile, 10th quantile, a 25th quantile, a 75th quantile, a 90th quantile, a 95th quantile, or a 99th quantile,
wherein the spreads of quantiles comprise a spread of the 1st quantile and the 99th quantile, a spread of the 5th quantile and the 95th quantile, a spread of the 10th quantile and the 90th quantile, or a spread of the 25th quantile and the 75th quantile.

9. The system of claim 1, wherein steps (a)-(e) are performed for each of the battery racks in the BESS subsystem simultaneously.

10. The system of claim 1, wherein the BESS subsystem is configured to store renewable electricity generated by solar power or wind power in order to reduce reliance on fossil fuel-based power generation and mitigate climate change effects.

11. A method for detecting and mitigating intermittent connections in a battery energy storage system (BESS) subsystem comprising a plurality of battery racks connected to a common bus comprising, for each respective rack in the BESS subsystem:
(a) receiving current time series data divided into timestamps, wherein each of the timestamps corresponds to a current value;
(b) determining a current rolling average for each respective data point of the time series data by averaging the current values of the timestamps over a specified time interval;
(c) determining a current delta for each respective data point of the plurality of data points of the current time series data, wherein the current delta is a difference between the current rolling average associated with the respective battery rack and a mean of the current rolling averages associated with the other battery racks in the BESS subsystem;
(d) analyzing a distribution profile of the current deltas to detect a current anomaly at the respective battery rack; and
(e) in response to detecting the current anomaly at the respective battery rack, generating an alert indicative of a faulty or intermittent connection at the respective battery rack, wherein the alert includes a direction to perform an action to correct or mitigate the faulty or intermittent connection, and displaying the alert on a user interface.

12. The method of claim 11, wherein analyzing the distribution profile to detect the current anomaly at the respective battery rack comprises:
determining quantiles and spreads of quantiles of the distribution profile; and
inputting the quantiles and the spreads of quantiles as features into a classifier to predict whether the respective battery rack has the current anomaly;
wherein the respective battery rack is predicted as having the current anomaly based on comparisons of values in the quantiles and the spreads of quantiles of the distribution profile to predefined current delta thresholds.

13. The method of claim 12, wherein the classifier comprises a random forest classifier, a support vector machine classifier, a gradient boosting machine classifier, or a logistic regression classifier.

14. The method of claim 13, wherein the classifier comprises the random forest classifier, and the comparisons of the values of the quantiles and the spreads of quantiles of the distribution profile to the predefined current delta thresholds are performed at decision tree branch points in the random forest classifier.

15. The method of claim 12, further comprising selecting the predefined current delta thresholds based on historical data patterns to reduce an occurrence of a false positive.

16. The method of claim 11, wherein the direction to perform an action to correct or mitigate the faulty or intermittent connection includes at least one of: inspecting module-to-module connections in the respective battery rack, inspecting a connection of the respective battery rack to the common bus, disconnecting the respective battery rack from the common bus, discharging the respective battery rack, ensuring fasteners at the respective battery rack are torqued to specification, replacing battery modules or packs at the respective battery rack, replacing connections at the respective battery rack, or activating an extinguishing fluid at the respective battery rack.

17. The method of claim 11, wherein the controller is further configured to: at least one of transmit the alert by at least one of email, SMS, or pager, thereby mitigating potential damage to the battery energy storage system.

18. The method of claim 11, wherein the quantiles comprise a 1st quantile, 5th quantile, 10th quantile, a 25th quantile, a 75th quantile, a 90th quantile, a 95th quantile, or a 99th quantile,
wherein the spreads of quantiles comprise a spread of the 1st quantile and the 99th quantile, a spread of the 5th quantile and the 95th quantile, a spread of the 10th quantile and the 90th quantile, or a spread of the 25th quantile and the 75th quantile.

19. The method of claim 11, wherein steps (a)-(e) are performed for each battery rack in the BESS subsystem simultaneously.

20. A non-transitory computer-readable medium having computer-executable instructions stored thereon that, in response to execution by one or more processors of a controller, cause the controller to perform operations for detecting and mitigating intermittent connections in a battery energy storage system (BESS) subsystem comprising a plurality of battery racks connected to a common bus, the operations comprising:
(a) receiving current time series data divided into timestamps, wherein each of the timestamps corresponds to a current value;
(b) determining a current rolling average for each respective data point of the time series data by averaging the current values of the timestamps over a specified time interval;
(c) determining a current delta for each respective data point of the plurality of data points of the time series data, wherein the current delta is a difference between the current rolling average associated with the respective battery rack and a mean of the current rolling averages associated with the other battery racks in the BESS subsystem;
(d) analyzing a distribution profile of the current deltas to detect a current anomaly at the respective battery rack; and
(e) in response to detecting the current anomaly at the respective battery rack, generating an alert indicative of a faulty or intermittent connection at the respective battery rack, wherein the alert includes a direction to perform an action to correct or mitigate the faulty or intermittent connection, and displaying the alert on a user interface.
